(19) United States
(12) Patent Application Publication
(10) Pub. No.: US 2013/0279127 A1
(43) Pub. Date: Oct. 24, 2013

(54) ELECTRONIC DEVICE WITH SHIELD FOR RECEIVING DIGITAL CARD

(71) Applicant: KUANG-YAO LIAO, Tu-Cheng (TW)

(72) Inventor: KUANG-YAO LIAO, Tu-Cheng (TW)

(73) Assignee: HON HAI PRECISION INDUSTRY CO., LTD., Tu-Cheng (TW)

(21) Appl. No.: 13/559,569

(22) Filed: Jul. 26, 2012

(30) Foreign Application Priority Data
Apr. 20, 2012 (TW) 101114229

(51) Int. Cl. H05K 9/00

(52) U.S. Cl. 361/752; 361/760

(57) ABSTRACT

An electronic device includes a circuit board, a shield and a metallic elastic element. The shield is grounded and is electrically connected to the circuit board to form a cavity with the circuit board and includes an opening and a digital card supporter. The metallic elastic element is placed into the cavity and is electrically connected to the circuit board. When a digital card is inserted to the shied through the opening, the digital card supporter supports the digital card and makes the digital card have a distance from the circuit board and the digital card is electrically connected to the metallic elastic element.

### BACKGROUND

1. Technical Field

The present disclosure relates to an electronic device with a shield for receiving a digital card.

2. Description of Related Art

Most electronic devices include shields and digital card slots. The shield is used to cover some electronic components of the electronic device to reduce electro magnetic interference (EMI). However, the shield and the digital card slot both set in one electronic device will waste the valuable space.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is an isometric view of an electronic device which only shows parts of components of the electronic device when a digital card is inserted into a shield of the electronic device in accordance with an exemplary embodiment.

FIG. 2 is an isometric view of the electronic device of FIG. 1 when the digital card is not inserted into the shield of the electronic device of FIG. 1.

FIG. 3 is an explored view of the electronic device of FIG. 1.

### DETAILED DESCRIPTION

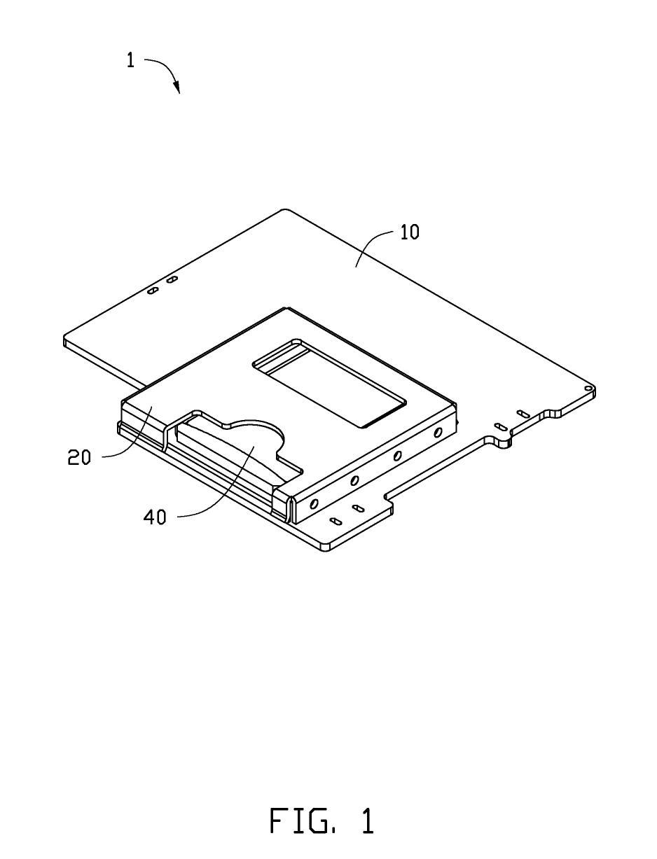

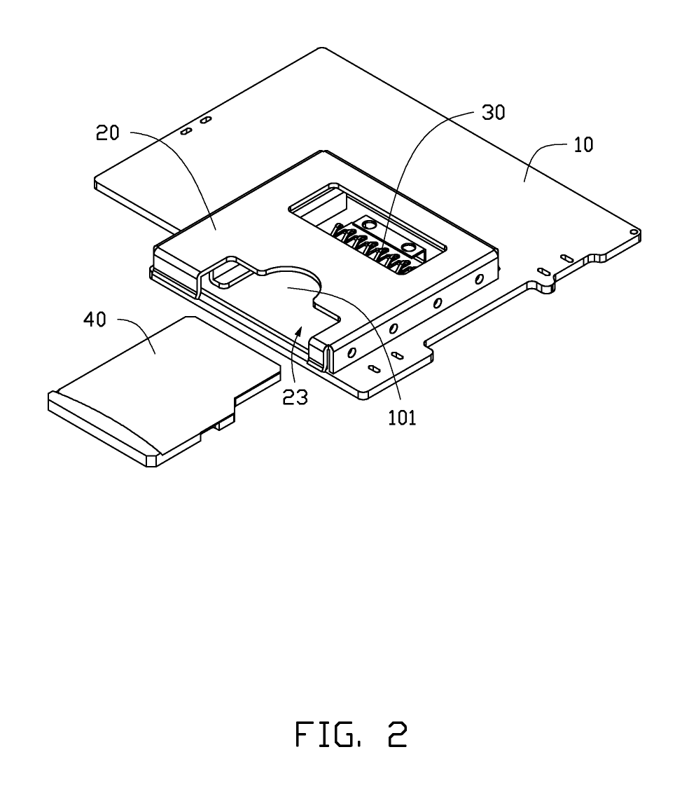

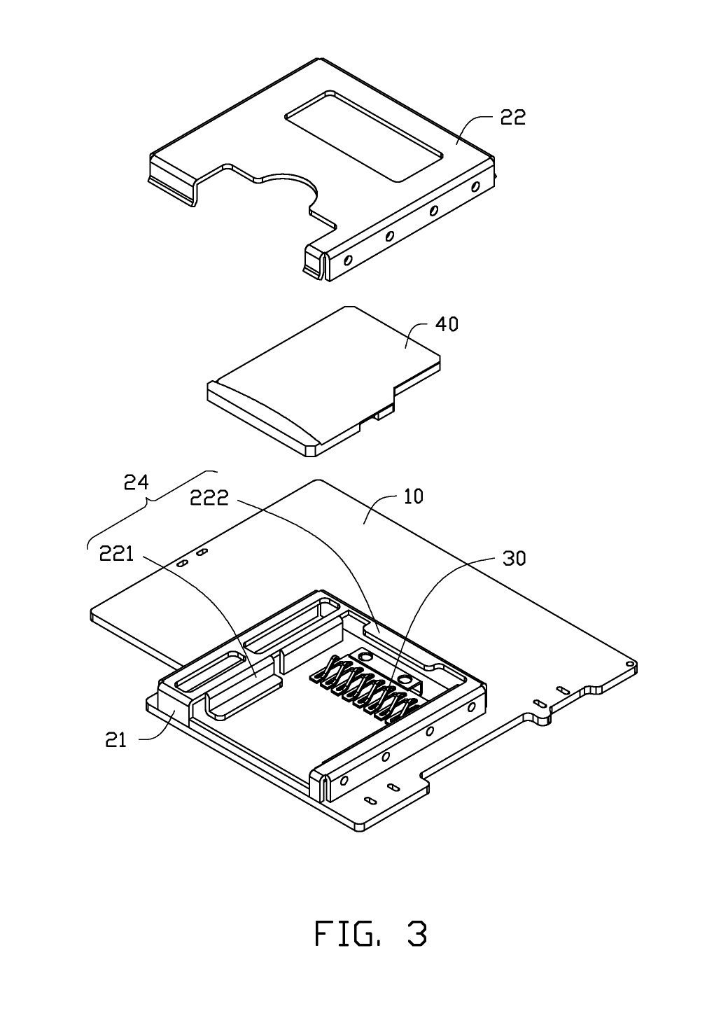

FIGS. 1-3 show an electronic device 1 in accordance to one embodiment. The electronic device 1 includes a circuit board 10, a shield 20, and a metallic elastic element 30. The shield 20 includes a metallic housing 21 and a metallic cover 22. The metallic cover 22 covers the metallic housing 21. The metallic housing 21 is grounded and electrically connected to the circuit board 10 to form a cavity 101. Other electronic components (not shown) of the electronic device can be placed into the cavity 101 and electrically connected to the circuit board 10. Thereby, the shield 20 is capable of shielding the EMI for the electronic components placed into the shield 20. In the embodiment, the metallic housing 21 is a rectangle bracket without a bottom.

The metallic elastic element 30 is also electronically connected to the circuit board 10 and placed into the cavity 101. In the embodiment, the metallic elastic element 30 is a group of metallic elastic pieces.

The metallic housing 21 and the metallic cover 22 form an opening 23. The metallic housing 21 further includes a digital card fixing part 24. A digital card 40 can be inserted to the shield 20 through the opening 23. The inserted card 40 is fixed by the digital card fixing part 24 and electrically connected to the metallic elastic element 30. After the digital card 40 is inserted to the shield 20, the digital card fixing part 24 maintains a space between the digital card 40 and the circuit board 10. The components that need to be shielded by the shield 20 can be placed under the digital card 40.

In the embodiment, the digital card fixing part 24 includes at least one supporter 221 and a locker 222. The supporter 221 supports the digital card 40. The locker 222 locks the inserted digital card 40 to the metallic housing 21.

In the embodiment, the digital card fixing part 24 includes two supporters 221. The two supporters 221 respectively extend from two relative inner walls 223 of the metallic housing 21. Each of the two supporters 221 includes two mutually perpendicular panels which make the supporter 221 be L-shaped. One of the two panels is connected to the metallic housing 21 and the other panel is parallel to the circuit board 10. The locker 222 is a protrusion which extends from the metallic housing 21. The protrusion is parallel to the circuit board 10 and locks the digital card 40 when the digital card 40 is inserted.

In other embodiments, the metallic housing 21 and the metallic cover 22 can be integrated into one piece.

Although, the present disclosure has been specifically described on the basis of preferred embodiments, the disclosure is not to be construed as being limited thereto. Various changes or modifications may be made to the embodiment without departing from the scope and spirit of the disclosure.

What is claimed is:

1. An electronic device comprising:
a circuit board;
a shield being grounded and electrically connected to the circuit board to form a cavity with the circuit board, comprising:
an opening; and
a digital card supporter; and
a metallic elastic element being placed into the cavity and electrically connected to the circuit board;
wherein when a digital card is inserted to the shield through the opening, the digital card supporter supports the digital card and make the digital card maintains a space from the circuit board and the digital card is electrically connected to the metallic elastic element.

2. The electronic device as described in claim 1, wherein the shield comprises a metallic housing and a metallic cover, the metallic cover covers the metallic housing to form the cavity, the metallic housing is grounded and electrically connected to the circuit board.

3. The electronic device as described in claim 2, wherein the metallic housing is a rectangle bracket without a bottom.

4. The electronic device as described in claim 2, when the metallic cover covers the metallic housing, the metallic housing and the metallic cover form the opening.

5. The electronic device as described in claim 2, wherein the digital card fixing part comprises two supporters and a locker, the two supporters respectively extend from two relative inner walls of the metallic housing, each of the two supporters comprises two mutually perpendicular panels which makes each of the two supporters be L-shaped, one of the two panels of each of the two supporter is connected to the metallic housing and the other panel is parallel to the circuit board.

6. The electronic device as described in claim 5, wherein the locker is a protrusion which extends from the metallic housing and parallel to the circuit board.

7. The electronic device as described in claim 1, wherein the digital card fixing part comprises at least one supporter and a locker, the supporter supports the inserted digital card, the locker locks the inserted digital card to the shield.
